(19) United States
(12) Patent Application Publication
(10) Pub. No.: US 2015/0376789 A1
(43) Pub. Date: Dec. 31, 2015

(54) VERTICAL HEAT TREATMENT APPARATUS AND METHOD OF OPERATING VERTICAL HEAT TREATMENT APPARATUS

(71) Applicant: TOKYO ELECTRON LIMITED, Tokyo (JP)

(72) Inventors: Yutaka MOTOYAMA, Oshu-shi (JP); Kohei FUKUSHIMA, Oshu-shi (JP); Masanobu MATSUNAGA, Nirasaki City (JP); Keiji TABUKI, Nirasaki City (JP); Yamato TONEGAWA, Nirasaki City (JP)

(21) Appl. No.: 14/845,673

(22) Filed: Sep. 4, 2015

Related U.S. Application Data
(63) Continuation-in-part of application No. 14/642,230, filed on Mar. 9, 2015, now abandoned.

(30) Foreign Application Priority Data
Mar. 11, 2014 (JP) 2014-047790
Jul. 9, 2015 (JP) 2015-137872

(51) Int. Cl. C23C 16/455; H01L 21/02; C23C 16/458

(52) U.S. Cl. CPC C23C 16/45587; C23C 16/4583; C23C 16/4581; H01L 21/0217; H01L 21/02271

(57) ABSTRACT

A vertical heat treatment apparatus includes: a gas supply part that supplies a film forming gas into a reaction chamber; and gas distribution adjusting members arranged above and below a region in which target substrates are disposed. The gas distribution adjusting members include a first plate-shaped member with convex and concave portions and a second plate-shaped member with convex and concave portions, the first plate-shaped member and the second plate-shaped member being arranged above and below each other, and the first plate-shaped member and the second plate-shaped member being arranged above a bottom plate of a substrate holding and supporting part and below a ceiling plate of a substrate holding and supporting part. The first plate-shaped member has a first surface area and the second plate-shaped member has a second surface area different from the first surface area.

### CROSS-REFERENCE TO RELATED APPLICATION

This application is a Continuation-in-part of application Ser. No. 14/642,230, filed Mar. 9, 2015, the entire contents of which are incorporated herein by reference; and is based upon and claims the benefit of priority from Japanese Patent Application Nos. 2014-047790, filed on Mar. 11, 2014 and 2015-137872, filed on Jul. 9, 2015, the entire contents of which are incorporated herein by reference.

### TECHNICAL FIELD

The present disclosure relates to a vertical heat treatment apparatus which forms films on all of a plurality of substrates and a method of operating the vertical heat treatment apparatus.

### BACKGROUND

In general, a film forming treatment such as ALD (Atomic Layer Deposition) or CVD (Chemical Vapor Deposition) is performed on a semiconductor wafer (hereinafter, referred to as a wafer) composed of a silicon substrate, etc. in order to fabricate a semiconductor product. The film forming treatment may be performed in a batch type vertical heat treatment apparatus for treating a plurality of wafers at a time. In this case, the wafers are moved and mounted onto a vertical wafer boat so that they are supported in the shape of shelves in multi-stages on the wafer boat. The wafer boat is carried (loaded) into an evacuable reaction chamber (reaction tube) from below, and a variety of gases are then supplied to the reaction chamber in a state that the interior of the reaction chamber is airtightly sealed, thereby performing the film forming treatment on the wafers. A method of performing the CVD with wafers mounted on the wafer boat is known as prior art.

Dummy wafers are held and supported in upper and lower sides of the wafer boat, and a plurality of wafers (for convenience of explanation, which may be described as product wafers), which are target substrates for manufacturing the semiconductor products, are held and supported such that the product wafers are inserted between dummy wafers located in the upper and lower sides of the wafer boat. In such a state, the wafer boat is carried into the reaction chamber as described above. As such, the reason why the dummy wafers are held and supported along with the product wafers in the wafer boat is to form films with high uniformity on the product wafers by smoothing the gas flow in a treatment chamber and by increasing uniformity of temperature among the product wafers, and is to prevent particles from being entrained on the product wafers when particles are produced from the wafer boat made of quartz. Unlike the product wafers, various films for forming the semiconductor products are not formed on surfaces of the dummy wafers, and thus convex and concave portions for forming wiring are not formed. Hereinafter, the dummy wafer may be described as a bare wafer.

As a semiconductor product is being miniaturized, the convex and concave portions are formed with high density on a surface of a product wafer and thus a surface area of the product wafer is gradually increasing. For this reason, in the film forming treatment, the amount of gas consumed by the product wafer is gradually increasing as compared with the amount (reacted amount) of processing gas consumed by a bare wafer. Therefore, for product wafers respectively supported in upper and lower sections of a wafer boat, a relatively large amount of processing gas is supplied by disposing bare wafers, which consumes a small amount of processing gas, in the vicinity of such product wafers. However, a larger amount of processing gas is consumed by product wafers that are supported above and below than the product wafers, which are supported in a middle section of the wafer boat. In this case, the product wafers supported in the middle section of the wafer boat consume a relatively small supply amount of processing gas per wafer. As a result, there is a concern that the thickness of films formed by the processing gas among the product wafers may vary.

In order to control the distribution of the processing gas for the product wafers, it was suggested that a film forming treatment is performed by CVD with dummy wafers mounted in a wafer boat. In this case, the dummy wafers are made of silicon and have a surface area approximately equal to that of a product wafer. Further, it was suggested that the dummy wafers are reused by immersing the dummy wafers in a hydrofluoric acid solution after the film formation process, thereby removing the formed film. However, such a configuration requiring such wet etching is disadvantageous in that the dummy wafers should be transferred from the vertical heat treatment apparatus to another apparatus, thereby causing a need for a great deal of labor.

### SUMMARY

Some embodiments of the present disclosure provide a technique that can improve uniformity of film thicknesses among the substrates when performing a film forming treatment by carrying a holding and supporting part for holding and supporting a plurality of substrates in the shape of shelves into a reaction chamber and supplying processing gas into the reaction chamber.

According to one embodiment of the present disclosure, there is provided a vertical heat treatment apparatus for performing a film forming treatment on a plurality of target substrates by heating the target substrates with a heating part in a state that the target substrates are held and supported by a substrate holding and supporting part in a vertical reaction chamber, each of the target substrates having a surface with convex and concave portions. The apparatus includes: a gas supply part that supplies a film forming gas into the reaction chamber; and gas distribution adjusting members arranged above and below a region in which the plurality of target substrates held and supported by the substrate holding and supporting part are disposed. The gas distribution adjusting members include a first plate-shaped member with convex and concave portions and a second plate-shaped member with convex and concave portions, the first plate-shaped member and the second plate-shaped member being arranged above and below each other, and the first plate-shaped member and the second plate-shaped member being arranged above a bottom plate of the substrate holding and supporting part and below a ceiling plate of the substrate holding and supporting part. The first plate-shaped member has a first surface area and the second plate-shaped member has a second surface area different from the first surface area.

According to another embodiment of the present disclosure, there is provided a method of operating a vertical heat treatment apparatus for performing a film forming treatment on a plurality of target substrates by heating the target substrates with a heating part in a state that the target substrates are held and supported by a substrate holding and supporting part in a vertical reaction chamber, each of the target substrates having a surface with convex and concave portions. The method includes: supplying a film forming gas into the reaction chamber by a gas supply part in a state that gas distribution adjusting members are arranged above and below a region in which the plurality of target substrates held and supported by the substrate holding and supporting part are disposed. The gas distribution adjusting members include a first plate-shaped member with convex and concave portions and a second plate-shaped member with convex and concave portions, the first plate-shaped member and the second plate-shaped member being arranged above and below each other, and the first plate-shaped member and the second plate-shaped member being arranged above a bottom plate of the substrate holding and supporting part and below a ceiling plate of the substrate holding and supporting part. The first plate-shaped member has a first surface area and the second plate-shaped member has a second surface area different from the first surface area.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal sectional side view of a vertical heat treatment apparatus according to a first embodiment of the present disclosure.

FIG. 2 is a cross sectional plan view of the vertical heat treatment apparatus.

FIG. 3 is a longitudinal sectional side view of a product wafer.

FIG. 4 is a timing chart of treatment of the vertical heat treatment apparatus.

FIG. 5 is a view illustrating a process in which a film is formed on the product wafer in the first embodiment.

FIG. 6 is a view illustrating a process in which a film is formed on the product wafer in a comparative example.

FIG. 7 is a graph showing the distribution of film thickness among wafers treated in the vertical heat treatment apparatus.

FIG. 8 is a view illustrating an example that product wafers are arranged in a wafer boat.

FIG. 9 is a longitudinal sectional side view of a vertical heat treatment apparatus according to a second embodiment.

FIG. 10 is a cross sectional plan view of the vertical heat treatment apparatus.

FIG. 11 is a graph showing the distribution of film thickness among wafers treated in the vertical heat treatment apparatus.

FIG. 12 is a graph showing the distribution of film thickness among wafers treated by using a wafer boat according to a third embodiment.

FIG. 13 is a graph showing the distribution of film thickness among wafers treated by using a wafer boat according to a fourth embodiment.

FIG. 14 is a view illustrating an arrangement of the wafers in a wafer boat according to a fifth embodiment.

FIG. 15 is a view illustrating another arrangement of the wafers in a wafer boat according to a fifth embodiment.

FIG. 16 is a view illustrating still another arrangement of the wafers in a wafer boat according to a fifth embodiment.

FIG. 17 is a view illustrating an example of a schematic configuration of a quartz wafer used in the fifth embodiment.

FIG. 18 is a view illustrating configuration of an injector used in an evaluation test.

FIG. 19 is a graph showing results of the evaluation test.

FIG. 20 is a graph showing results of the evaluation test.

FIG. 21 is a graph showing results of the evaluation test.

### DETAILED DESCRIPTION

Hereinafter, some embodiments of the present disclosure will be described with reference to the accompanying drawings. Throughout the drawings, like reference numerals are used to designate like elements. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

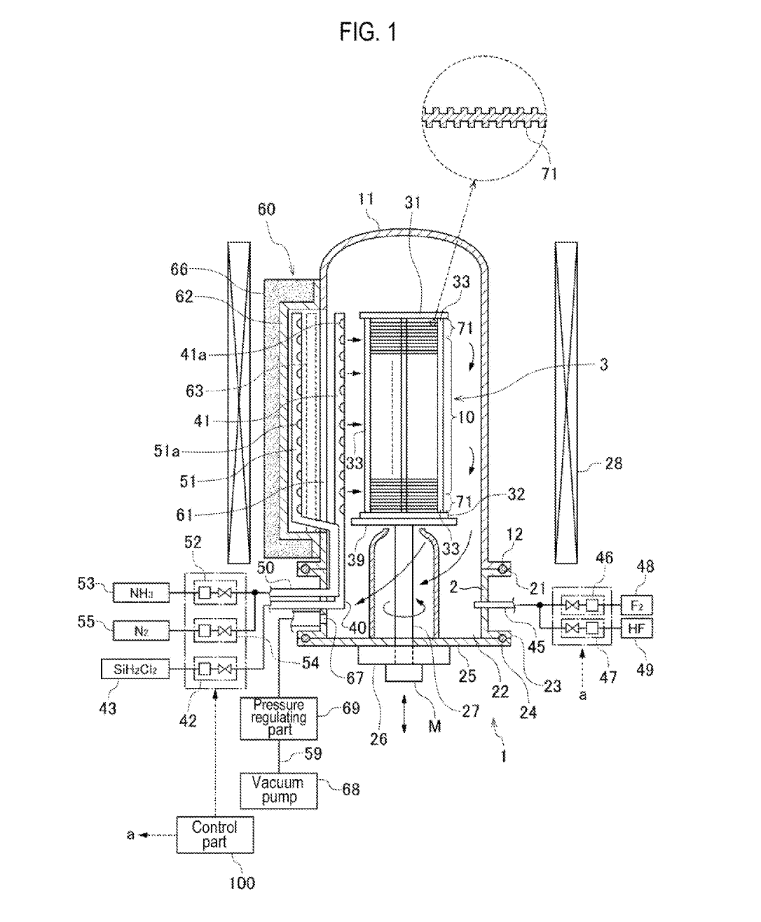

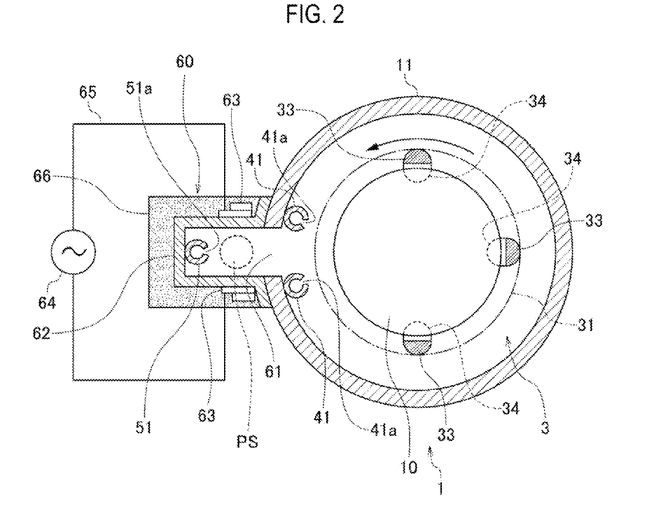

A first embodiment of the present disclosure will be described based on the accompanying drawings. FIGS. 1 and 2 are schematic longitudinal and cross sectional views of a vertical heat treatment apparatus 1 according to the present disclosure, respectively. Reference numeral 11 in FIGS. 1 and 2 designates a reaction tube which, for example, forms a treatment chamber made of quartz in the shape of a vertical cylinder. In addition, a peripheral portion of a lower end opening of the reaction tube 11 is formed integrally with a flange 12. A manifold 2, for example, which is formed of stainless steel in the shape of a cylinder, is connected to a lower surface of the flange 12 with a sealing member 21 such as an O-ring interposed therebetween.

A lower end of the manifold 2 is open as a loading/unloading opening (furnace opening), and a peripheral portion of the opening 22 is formed integrally with a flange 23. In a lower portion of the manifold 2, a lid 25 made of, e.g., quartz, is installed to be opened and closed in a vertical direction by a boat elevator 26. The lid 25 airtightly closes the opening 22 on the lower surface of the flange 23 with a sealing member 24 such as an O-ring interposed therebetween. A rotating shaft 27 is installed to penetrate a central portion of the lid 25. A wafer boat 3 that is a substrate holding and supporting part is mounted on an upper end of the rotating shaft 27 with a stage 39 interposed therebetween.

An L-shaped first raw material gas supply pipe 40 is inserted through a sidewall of the manifold 2. At a leading end of the first raw material gas supply pipe 40, as shown in FIG. 2, two first raw material gas supply nozzles 41, which are made of quartz pipes extending upward in the reaction tube 11, are disposed with an elongated opening 61 of a plasma generating part 60 described later interposed therebetween. A plurality (large number) of gas discharge holes 41a are formed at predetermined intervals in a lengthwise direction of the first raw material gas supply nozzles 41. A gas can be approximately uniformly discharged from the respective gas discharge holes 41a in a horizontal direction. In addition, a supply source 43 of a silane-based gas, which is a first raw material gas, such as SiH₂Cl₂ (dichlorosilane: DCS) gas, is connected to a base end of the first raw material gas supply pipe 40 via a supply device group 42.

Further, an L-shaped second raw material gas supply pipe 50 is inserted through the sidewall of the manifold 2. A second raw material gas supply nozzle 51 made of quartz is installed at a leading end of the second raw material gas supply pipe 50. The second raw material gas supply nozzle 51 extends upward in the reaction tube 11, is bent while extending upward and is installed in the plasma generating part 60 described later. A plurality (large number) of gas discharge holes 51a are formed at predetermined intervals in a lengthwise direction of the second raw material gas supply nozzle 51. A gas can be approximately uniformly discharged from the respective gas discharge holes 51a in a horizontal direction. In addition, a base end of the second raw material gas supply pipe 50 is bifurcated into two branches so that a supply source 53 of NH₃ (ammonia) gas that is a second raw material gas is connected to one branch of the second raw material gas supply pipe 50 via a supply device group 52, and a supply source 55 of N₂ (nitrogen) gas is connected to the other branch of the second raw material gas supply pipe 50 via a supply device group 54.

Moreover, one end of a cleaning gas supply pipe 45 is inserted through a sidewall of the manifold 2. The other end of the cleaning gas supply pipe 45 is bifurcated into two branches which in turn are connected to a gas supply source 48 of F₂ (fluorine) gas and a gas supply source 49 of HF (hydrogen fluoride) via supply device groups 46 and 47, respectively. Thus, a mixed gas of F₂ and HF may be supplied as a cleaning gas into the reaction tube 11. The cleaning gas is not limited to a gas employing such fluorine gas or hydrogen fluoride gas as a major component, but may be, for example, a gas employing another fluorine compound as a major component. Furthermore, each of the supply device groups 42, 46, 47, 52 and 54 is comprised of a valve, a flow rate adjuster, etc.

Further, the plasma generating part 60 is provided on a portion of the sidewall of the reaction tube 11 in a height direction of the reaction tube. The plasma generating part 60 is constructed in a manner that the vertically elongated opening 61 is formed by vertically cutting out the sidewall of the reaction tube 11 by a predetermined width and a vertically elongated compartment wall 62 made of, e.g., quartz, which is concave in cross section, is then airtightly welded on an outer wall of the reaction tube 11 to cover the opening 61. A region surrounded by the compartment wall 62 becomes a plasma generating region PS.

The opening 61 is formed to be sufficiently long in the vertical direction in order to cover all of wafers, which are held and supported by the wafer boat 3, in the height direction. Further, a pair of elongated plasma electrodes 63 facing each other in the lengthwise direction (vertical direction) is provided on outer surfaces of both sidewalls of the compartment wall 62. A high frequency power source 64 for plasma generation is connected to the plasma electrodes 63 via a power supplying line 65. Plasma can be generated by applying a high frequency voltage of, for example, 13.56 MHz to the plasma electrodes 63. In addition, an insulating protection cover 66 made of, for example, quartz is attached to cover the compartment wall 62 at the outside of the compartment wall 62.

Further, an exhaust port 67 is open in the manifold 2 to make the atmosphere in the reaction tube 11 be vacuum-exhausted. The exhaust port 67 is connected to an exhaust pipe 59, which has a vacuum pump 68 constituting a vacuum evacuating means for depressurizing and evacuating the interior of the reaction tube 11 to a desired degree of vacuum, and a pressure regulating part 69 comprised of, for example, a butterfly valve. As shown in FIG. 1, a cylindrical heater 28, which is a heating means for heating the reaction tube 11 and wafers in the reaction tube 11, is also installed to surround the outer circumference of the reaction tube 11.

Further, the vertical heat treatment apparatus 1 includes a control part 100. The control part 100 is comprised of, for example, a computer and configured to control the boat elevator 26, the heater 28, the supply device groups 42, 46, 47, 52 and 54, the high frequency power source 64, the pressure regulating part 69, and the like. More specifically, the control part 100 includes a memory part configured to store sequence programs for performing a series of treatment steps, which will be described later, carried out in the reaction tube 11, a means for reading out instructions of the respective programs and outputting control signals to the respective components, and the like. Moreover, the programs are stored in the control part 100 in a state that they are stored in a storage medium such as a hard disk, a flexible disk, a compact disk, a magneto-optical (MO) disk, a memory card or the like.

Next, the wafer boat 3 will be further explained. The wafer boat 3 is made of quartz, and includes a ceiling plate 31 and a bottom plate 32 which are placed parallel to each other during a film forming treatment. The ceiling plate 31 and the bottom plate 32 are respectively connected to one end and the other end of each of three pillars 33 extending in the vertical direction. Supports 34 (see FIG. 2) are provided in multi-stages for each of the pillars 33 in order to horizontally hold and support wafers on the supports 34. Thus, wafers in the wafer boat 3 are held and supported in the shape of shelves in multi-stages. A region where a wafer is supported on each of the supports 34 is referred to as a slot, and 120 slots are provided in this example. In addition, the respective slots are designated by numbers 1 to 120, and a smaller number is assigned to a slot positioned closer to an upper end.

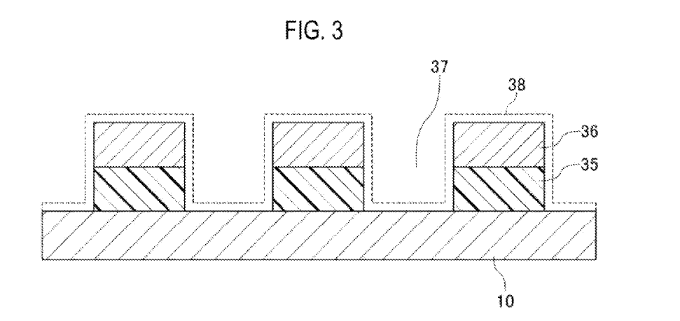

In the first embodiment, wafers 10 and wafers 71 are mounted in the slots. The wafer 10 is a product wafer for manufacturing a semiconductor product described in the BACKGROUND, and is made of, for example, a silicon substrate. As shown in FIG. 3, convex and concave portions for forming wiring are formed on a surface of the wafer 10. In FIG. 3, the reference numeral 35 designates a polysilicon film, and the reference numeral 36 designates a tungsten film. The reference numeral 37 is a concave portion formed in the films 35 and 36. The reference numeral 38 is a SiN film (silicon nitride film) formed by the vertical heat treatment apparatus 1.

The wafer 71 is a wafer made of quartz (hereinafter, referred to as a quartz wafer). The quartz wafer 71 is configured to have a contour corresponding to that of the wafer 10 when seen from the top, so as to be mounted in the wafer boat 3. In order to prevent the wafer from breaking during handling, the thickness of the quartz wafer 71 is, for example, slightly greater than that of the wafer 10 and is, for example, 2 mm. A longitudinal sectional side view of the quartz wafer 71 is shown in an enlarged scale within a dotted-line circle depicted at the end of a dotted-line arrow of FIG. 1. As shown herein, convex and concave portions are formed in front and back sides of the quartz wafer 71. The convex and concave portions are formed by laser processing, mechanical machining, or the like.

A surface area per unit region, which is obtained by dividing the surface area of the wafer 10 by a surface area calculated based on an external dimension of the wafer 10, is referred to as S0. The surface area obtained based on the external dimension is a virtual surface area obtained by assuming that the surface of the wafer 10 is a flat surface without considering concave portions 37 of the surface of the wafer 10. That is, a value obtained by dividing the actual surface area of the wafer 10 by the virtual surface area is the surface area per unit region S0.

The surface area of the wafer, which is referred to herein, is the area of a top side (front side) of the wafer+the area of a bottom side (back side) of the wafer. In addition, a surface area per unit region, which is obtained by dividing the surface area of the quartz wafer 71 by a surface area calculated based on external dimension of the quartz wafer 71, is referred to as S. In the same manner as the wafer 10, the surface area obtained based on the external dimension of the quartz wafer 71 is a virtual surface area obtained by assuming that the front and back sides of the quartz wafer 71 are flat surfaces without considering concave portions formed in the front and back sides of the quartz wafer 71. In order to adjust a gas distribution in the vertical direction of the wafer boat 3 as described later, S/S0 is set to be, for example, 0.06 or more. In this example, the quartz wafer 71 is configured such that S/S0=0.6.

If S/S0 is set to be less than 0.06, too much amount of gas is consumed by the wafers 10, which makes it difficult to adjust film thickness of each wafer 10 using quartz wafers 71. For this reason, S/S0 is set to be, for example, 0.06 or more. As shown in FIG. 1, the quartz wafers 71 are held and supported in a plurality of slots at upper and lower sections among the slots of the wafer boat 3. The wafers 10 are held and supported in slots in which the quartz wafers 71 are not held and supported. Thus, a group of wafers 10 is held and supported by the wafer boat 3 such that it is inserted between above and below quartz wafers 71. The quartz wafers 71 may be configured to be detachably attached to the wafer boat 3, in the same manner as the wafers 10, or may be configured to be fixed to the wafer boat 3. The wafers 10 are transferred to and mounted in the wafer boat 3 by a transferring/mounting mechanism (not shown). If the quartz wafers 71 are configured to be detachably attached to the wafer boat 3, the quartz wafers are transferred and mounted, for example, by the transferring/mounting mechanism, in the same manner as the wafers 10. In this example, the quartz wafers 71 are fixed to the wafer boat 3 for easy handling.

Next, the film forming treatment performed in the vertical heat treatment apparatus 1 will be described. First, a group of wafers 10 is mounted in a wafer boat 3 such that the group of wafers 10 is inserted between the above and below quartz wafers 71 as described above. Then, the wafer boat 3 is lifted from below and is carried (loaded) into the reaction tube 11 which was previously set to a predetermined temperature. The lower opening 22 of the manifold 2 is closed by the lid 25, thereby hermetically sealing the interior of the reaction tube 11.

Then, the interior of the reaction tube 11 is vacuum-evacuated by the vacuum pump 68 to a predetermined degree of vacuum. Subsequently, the pressure in the reaction tube 11 becomes, for example, 665.5 Pa (5 Torr), and DCS gas and N₂ gas are supplied to the reaction tube 11 from the first raw material gas supply nozzles 41, for example, respectively at flow rates of 1,000 sccm and 2,000 sccm, for example, for three seconds in a state that the high frequency power source 64 is turned off. Thus, molecules of the DCS gas are adsorbed onto a surface of each of the wafers 10 held and supported in the shape of shelves in the rotating wafer boat 3 (Step S1).

Thereafter, the supply of the DCS gas is stopped. The N₂ gas is continuously supplied to the reaction tube 11 and the pressure in the reaction tube 11 becomes, for example, 120 Pa (0.9 Torr), thereby purging the interior of the reaction tube 11 with the N₂ gas (Step S2). Then, while the pressure in the reaction tube 11 becomes, for example, 54 Pa (0.4 Torr), NH₃ gas and N₂ gas are supplied to the reaction tube 11 from the second raw material gas supply nozzle 51, for example, respectively at flow rates of 5,000 sccm and 2,000 sccm, for example, for 20 seconds in a state that the high frequency power source 64 is turned on (Step S3). Thus, active species, such as N radicals, H radicals, NH radicals, NH₂ radicals, and NH₃ radicals, react with the molecules of the DCS gas, thereby generating a SiN film 38 shown in FIG. 3.

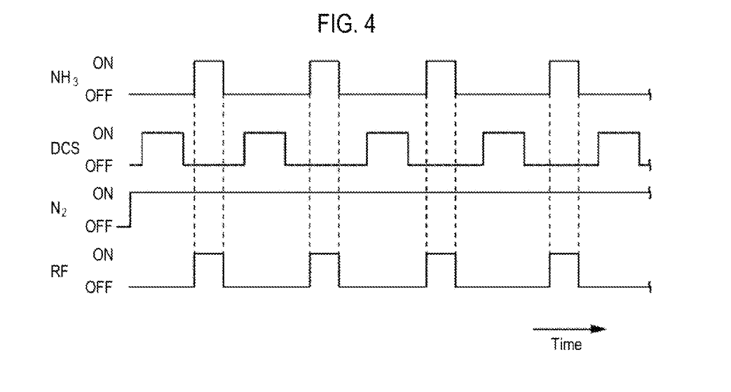

Thereafter, the supply of the NH₃ gas is stopped. The N₂ gas is continuously supplied to the reaction tube 11 and the pressure in the reaction tube 11 becomes, for example, 106 Pa (0.8 Torr), thereby purging the interior of the reaction tube 11 with the N₂ gas (Step S4). FIG. 4 is a timing chart illustrating a timing at which each gas is supplied and a timing at which the high frequency power source 64 is turned on. As shown in this chart, by repeating Steps S1 to S4 plural times, e.g., 200 times, thin films of SiN film 38 are laminated on a layer-by-layer basis and grown on the surface of the wafer 10, thereby forming the SiN film 38 having a desired thickness on the surface of the wafer 10.

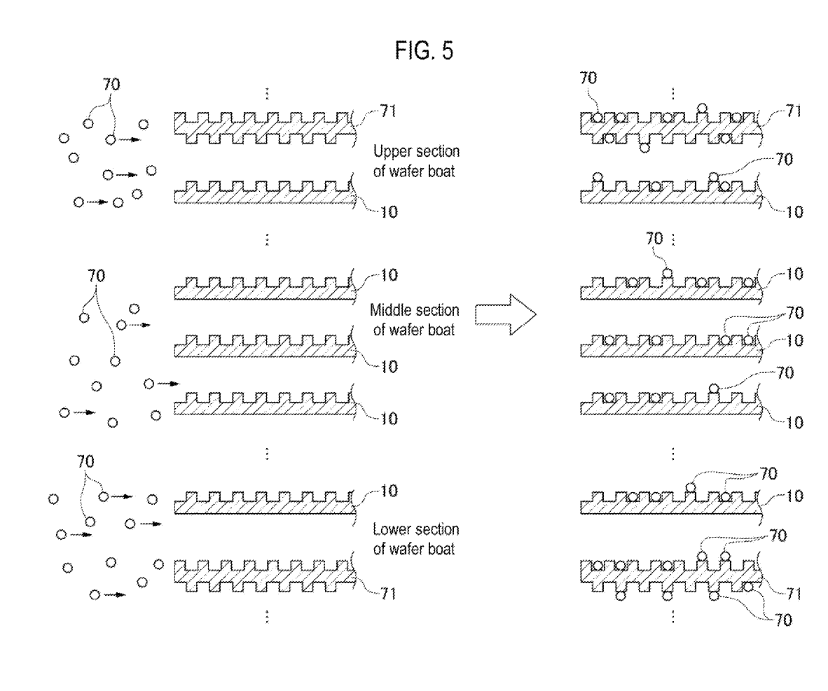

The status of the wafer 10 and quartz wafer 71 when the DCS gas is supplied during the film forming treatment will be described using a schematic view of FIG. 5. In FIG. 5, the reference numeral 70 designates molecules of the DCS gas. In a middle section of the wafer boat 3, the wafers 10 having large surface areas by forming a surface with convex and concave portions are disposed in multi-stages, and the molecules 70 supplied to the middle section of the wafer boat 3 are consumed for (adsorbed onto) the wafers 10. As such, the molecules 70 are consumed such that they are distributed with high uniformity among the wafers 10. Thus, an adsorption amount of the molecules 70 per sheet of the wafer 10 is prevented from being excessive.

Similarly to the wafers 10 held and supported in the middle section, wafers having large surface areas, i.e., quartz wafers 71, exist in the vicinity of the wafers 10 held and supported in upper and lower sections of the wafer boat 3. Thus, the molecules 70 supplied to the upper and lower sections of the wafer boat 3 are consumed such that they are distributed with high uniformity on the wafers 10 and the quartz wafers 71. That is, the adsorption amount of molecules 70 onto the quartz wafer 71 is relatively large due to the large surface area of the quartz wafer 71. Thus, it is possible to prevent excessive molecules 70 from being supplied to the wafer 10, thereby suppressing an excessive adsorption amount of molecules 70 per sheet of the wafer 10.

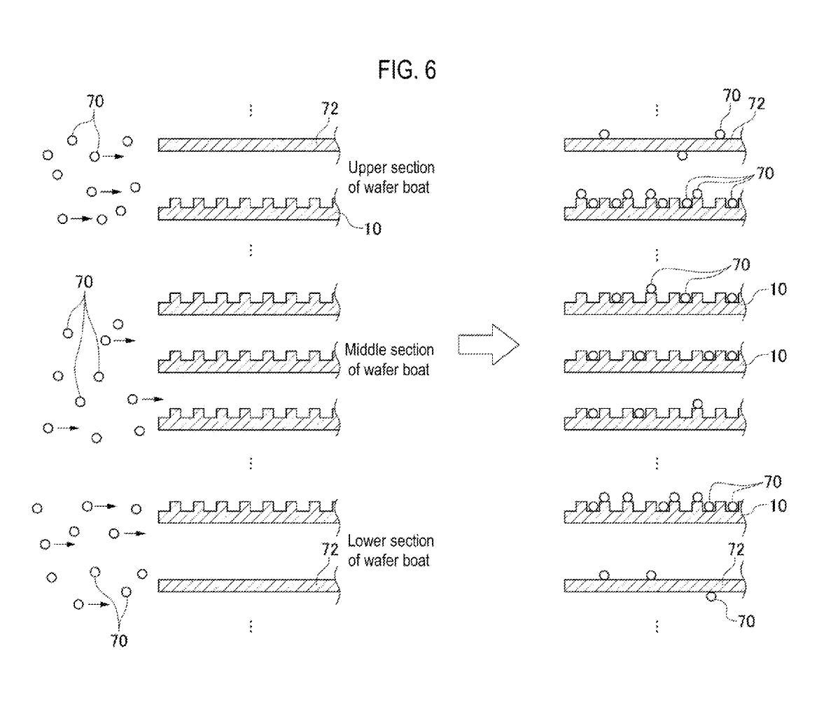

FIG. 6 shows a schematic view for the purpose of comparison with FIG. 5. FIG. 6 illustrates a state that the molecules 70 are adsorbed onto the wafers 10 when performing a film forming treatment by disposing a bare wafer 72 described in the BACKGROUND, instead of the quartz wafer 71, into each slot in which the quartz wafer 71 described above is disposed. As previously explained above, the bare wafer 72 is made of, for example, silicon. Since the bare wafer 72 does not have any convex and concave portions for forming a device on its surfaces, it has a small surface area. Even in a case where the bare wafers 72 are disposed, as described in FIG. 5, the molecules 70 are distributed onto each of the wafers 10 in the middle section of the wafer boat 3, thereby suppressing the adsorption amount of molecules 70 per sheet of the wafer 10. However, for the wafers 10 held and supported in the upper and lower sections of the wafer boat 3, the bare wafers 72 exist in the vicinity of the wafers 10 and they have a small amount of adsorption of molecules 70 due to small surface areas. Thus, surplus molecules 70 that are not consumed at the bare wafers 72 are adsorbed onto the wafers 10.

As illustrated in FIGS. 5 and 6, because the quartz wafers 71 are held and supported by the wafer boat 3, the molecules 70 are prevented from being excessively adsorbed onto the wafers 10 at the upper and lower sections of the wafer boat. As a result, the molecules 70 are adsorbed with high uniformity among the wafers. Although there was described an example in which the molecules 70 of the DCS gas are adsorbed, the quartz wafers 71 held and supported by the wafer boat 3 also allow radicals generated from NH₃ and N₂ gases to be supplied with high uniformity among the wafers 10, as the molecules 70. In addition, the supplied radicals react with the molecules 70.

After the process is terminated by repeating Steps S1 to S4 200 times as described above, the wafer boat 3 is unloaded from the reaction tube 11. After the wafers 10 for which the film formation treatment is terminated are taken out from the wafer boat 3, the wafer boat 3 is again loaded into the reaction tube 11 and the opening 22 is closed. The interior of the reaction tube 11 is vacuum-evacuated and is set to a predetermined pressure, while setting the interior temperature of the reaction tube 11 to, for example, 350 degrees C. Then, the aforementioned cleaning gas composed of F₂ and HF is supplied to the reaction tube 11. Accordingly, the SiN films 38 formed in reaction tube 11 and on the wafer boat 3 and quartz wafers 71 are etched and removed from the reaction tube 11 through entrainment in an exhaust stream. Thereafter, the supply of the cleaning gas is stopped, and the wafer boat 3 is unloaded from the reaction tube 11. Then, subsequent wafers 10 are mounted in the wafer boat 3, and the film forming treatment is performed on the subsequent wafers 10 according to Steps S1 to S4.

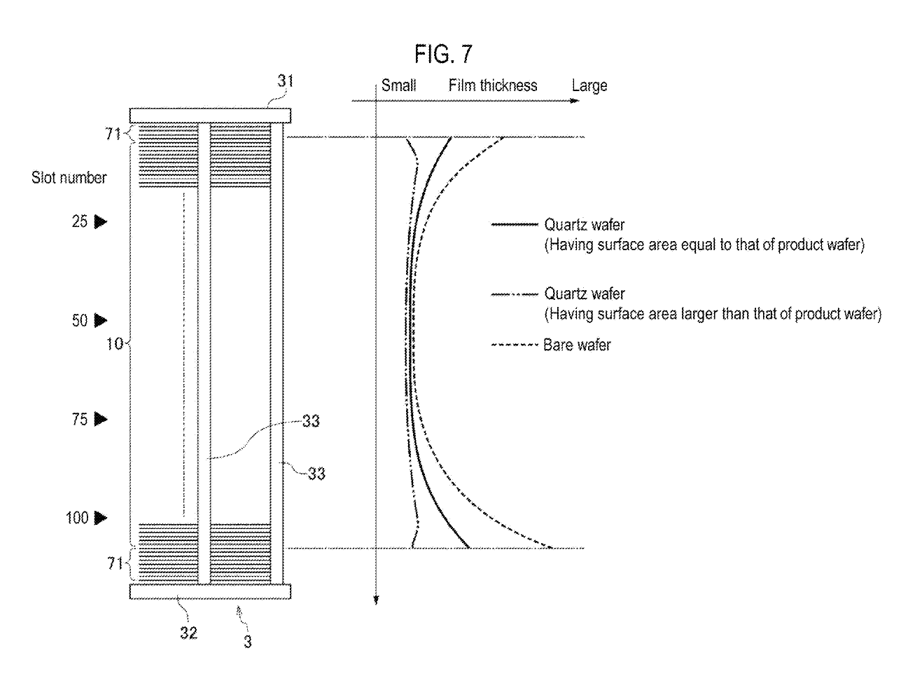

FIG. 7 shows a graph illustrating relationships between film thicknesses of the wafers 10 and positions of the slots. The abscissa axis of the graph corresponds to the film thicknesses of the wafers 10, and the ordinate axis of the graph corresponds to the positions of the slots. Slot numbers are assigned to the wafer boat 3 such that the heights of the slots correspond to scales of the ordinate axis of the graph. A curve indicated by a dotted-line represents data obtained based on an experiment, and shows the distribution of film thickness of the wafers 10 in the respective slots when the film forming treatment is performed by holding and supporting the bare wafers 72, instead of the quartz wafers 71, in the wafer boat 3 as described in FIG. 6. For the reason described with reference to FIG. 6, the film thicknesses of the wafers 10 gradually increase from the slots in the middle section of the wafer boat 3 toward the slots at the upper and lower sections. Hence, differences in film thickness between the wafers 10 in the slots in the upper and lower sections and the wafers 10 in the slots in the middle section are relatively large. That is, a variation in film thickness among the slots is large. Further, in the wafer boat 3 in FIG. 7, there is shown a state of holding and supporting the quartz wafers 71 according to an embodiment, not the bare wafers 72.

A curve indicated by a solid-line in FIG. 7 is a curve of the case that the film forming treatment is performed by disposing the quartz wafers 71 as illustrated in FIGS. 1 to 5, and shows the effect of the first embodiment. For the reason described with reference to FIG. 5, excessive supply of a gas to the wafers 10 at the upper and lower sections of the wafer boat 3 is suppressed by the quartz wafers 71. Thus, as shown in the curve, an increase in the film thickness of each of the wafers 10 at the upper and lower sections is suppressed. As a result, it is possible to improve the uniformity of film thicknesses among the wafers 10 in the slots.

As the surface areas of the quartz wafers 71 become larger, it is believed that the supply of a gas to the wafers 10 at the upper and lower sections of the wafer boat 3 can be suppressed. In FIG. 7, a curve indicated by a two-dot chain line is a curve showing the distribution of film thickness in a case where the surface areas of the quartz wafers 71 are greater than those of the wafers 10. The surface areas of the quartz wafers 71 are determined to allow the distribution of appropriate film thickness to be obtained according to the surface areas of the wafers 10. Even when only one quartz wafer 71 is provided at each of the upper and lower sections of the wafer boat 3, a gas distribution for the wafers 10 can be adjusted as described above. However, it is preferable to provide a plurality of quartz wafers in view of controlling a temperature distribution among the wafers 10.

Further, since the quartz wafer 71 is made of quartz, corrosion, which is caused by the cleaning gas including the fluorine gas or a gas composed of a fluorine compound, is suppressed as compared with a wafer made of Si. For this reason, the quartz wafer 71 can be repeatedly used in the film forming treatment as described above. Further, since it is unnecessary to transport the quartz wafer 71 to an apparatus for performing wet etching in order to perform cleaning, it is possible to save labor for operating such an apparatus.

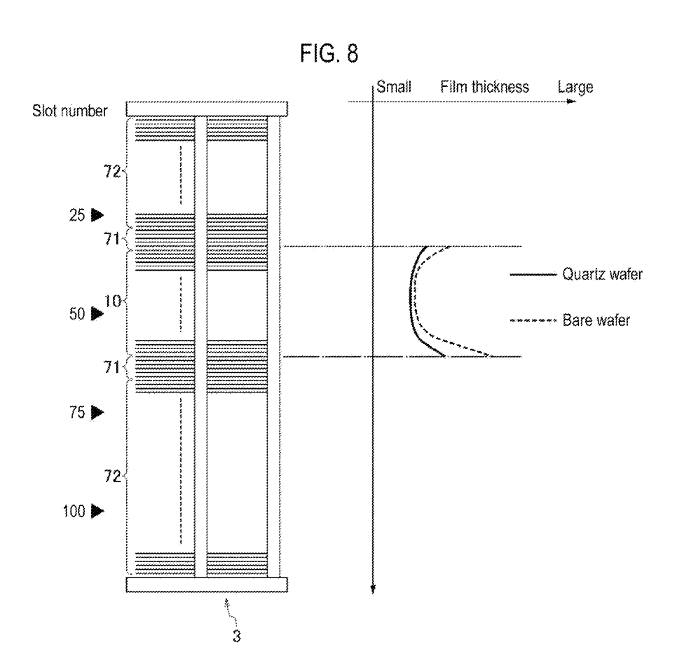

Meanwhile, there is a case where the film forming treatment is performed with a relatively small number of wafers 10 held and supported in the wafer boat 3. In this case, for example, the film forming treatment is performed by holding and supporting the wafers 10 as shown in FIG. 8. Specifically, the wafers 10 are held and supported in slots in the middle section. In the example of FIG. 8, the wafers 10 are consecutively mounted in slots around Slot Nos. 35 to 60. Then, the quartz wafers 71, e.g., a plurality of quartz wafers, are held and supported in slots respectively above and below Slot Nos. 35 to 60. In the example as shown in FIG. 8, about five quartz wafers 71 are held and supported in the slots respectively above and below the slots with the wafers 10 held and supported.

The bare wafers 72 are held and supported in slots respectively at upper and lower sections of the wafer boat 3 so that a group of quartz wafers 71 and a group of wafers 10 are inserted between the bare wafers 72. The bare wafers 72 are mounted to prevent disturbance of the flow of a gas in the reaction tube 11 or distortion of the temperature distribution in the wafers 10. As such, any one of the wafers 10, the quartz wafers 71 and the bare wafers 72 is held and supported in each of Slot Nos. 1 to 120.

Similarly to FIG. 7, FIG. 8 also is a graph showing the distribution of film thickness. A curve indicated by a solid-line shows the distribution of film thickness among the wafers 10 when performing a film forming treatment on the wafers 10 with the quartz wafers 71 mounted in the wafer boat 3 as described above. A curve indicated by a dotted-line shows the distribution of film thickness of the wafers 10 when performing a film forming treatment by holding and supporting the bare wafers 72, instead of the quartz wafers 71, in the above explained slots in which the quartz wafers 71 are held and supported. As illustrated in the graph of FIG. 8, the quartz wafers 71 can be mounted in the wafer boat 3 as described above even when the film forming treatment is performed on a small number of wafers 10. For the reason illustrated with reference to FIGS. 5 and 6, it is possible to prevent an increase in the film thickness of each of the wafers 10, which are disposed at the upper and lower sections of the wafer boat 3, in the group of wafers 10 mounted in the wafer boat 3. As a result, it is possible to improve uniformity of film thicknesses among the wafers 10.

### Second Embodiment

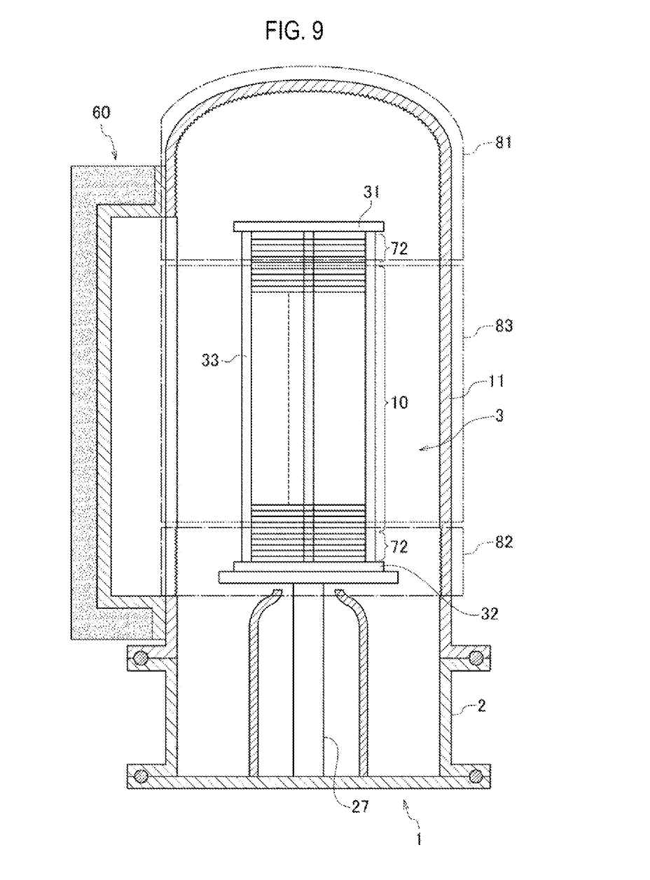

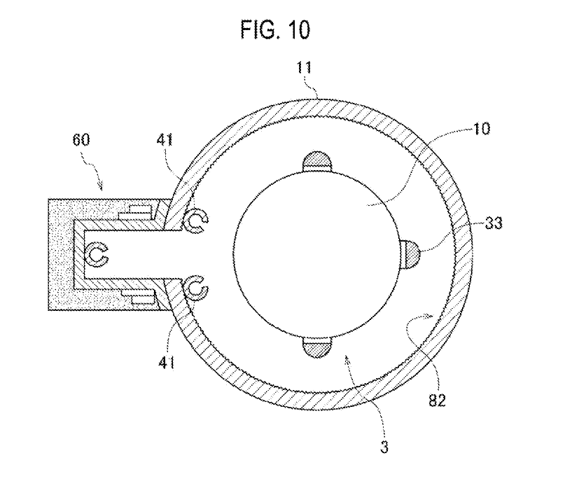

As explained in FIG. 5, if there are members having relatively large surface areas above and below a group of wafers 10 mounted in the wafer boat 3, it is possible to adjust the distribution of film thickness among the wafers 10 by reducing supply amounts of the gas above and below the group of wafers 10. Thus, the member for adjusting gas distribution is not limited to the quartz wafer 71. FIGS. 9 and 10 show a longitudinal sectional side view and a cross sectional plan view of a vertical heat treatment apparatus 1 according to a second embodiment, respectively. A vertical heat treatment apparatus 1 according to the second embodiment is different from that of the first embodiment as to the configuration of a reaction tube 11 but the other components are constructed in the same manner. In FIGS. 9 and 10, some of the members described in the first embodiment are omitted.

In the vertical heat treatment apparatus 1 according to the second embodiment, convex and concave portions are formed in an upper region 81 including a ceiling surface and an upper side circumferential surface of the reaction tube 11 and in a lower region 82 that is a lower side circumferential surface of the reaction tube 11, in order to increase the surface areas. The upper and lower regions 81 and 82 are inner circumferential surfaces of the reaction tube 11. When the wafer boat 3 is accommodated in the reaction tube 11, the lower region 82 includes a region lower than the group of wafers 10 mounted in the wafer boat 3. The convex and concave portions of the upper and lower regions 81 and 82 are formed, for example, by means of a sandblasting treatment or a chemical solution treatment. If the sandblasting treatment is performed, arithmetic average roughness (Ra) is, for example, 0.4 to 4.0 μm. If the chemical solution treatment is performed, the arithmetic average roughness (Ra) is, for example, 0.3 to 4.0 μm. Convex and concave portions may be formed also in the quartz wafer 71 according to the first embodiment by means of the sandblasting or chemical solution treatment. Further, in the same manner as the quartz wafer 71, convex and concave portions may be formed in the reaction tube 11 by laser processing.

By forming roughness (convex and concave portions) as described above, the upper and lower regions 81 and 82 serve to adjust supply distribution of a gas in the same manner as quartz wafer 71 according to the first embodiment. To this end, if a surface area per unit region for each of the upper and lower regions 81 and 82 is S, the convex and concave portions are formed such that the relationship S/S0 with the surface area S0 per unit region of the wafer 10 is set to be 0.06 or more as in the first embodiment. The surface area of each of the upper and lower regions 81 and 82 is a surface area of a surface facing the treatment space to which a gas is supplied. To further explain the surface area S per unit region of the upper region 81 in detail as an example, it is assumed that the upper region 81 has no convex and concave portions and is cut to obtain a segment having an area A equal to the area of a region surrounded by the contour of the wafer 10. If the surface area of a surface of the cut segment facing the treatment space in the reaction tube 11 is B, S is B/A. The surface area B is a surface area measured under the assumption that there are convex and concave portions. The surface area S of the lower region 82 is calculated in the same manner.

In the inner side circumferential surface of the reaction tube 11, a region interposed between the upper and lower regions 81 and 82 is referred to as a middle region 83. The middle region 83 is positioned around an outer periphery of the group of wafers 10 when the wafer boat 3 is loaded into the reaction tube 11. The middle region 83 is configured to have a smooth surface without being subjected to the sandblasting or chemical solution treatment. That is, the roughness of the middle region 83 is smaller than that of the upper and lower regions 81 and 82.

The film forming treatment and cleaning treatment are performed also in the vertical heat treatment apparatus 1 according to the second embodiment in the same manner as the first embodiment. By forming the rough inner circumferential surface of the reaction tube 11 as described above, a gas supplied to upper and lower sections of the wafer boat 3 during the film forming treatment is consumed in the upper and lower regions 81 and 82. Accordingly, as in the first embodiment, it is possible to prevent the gas from being excessively supplied to the wafers 10 held and supported at the upper and lower sections of the wafer boat 3. As such, the upper and lower regions 81 and 82 of the reaction tube 11 perform the same function as the quartz wafers 71 of the first embodiment as described above. Hence, unlike the first embodiment, the bare wafers 72, instead of the quartz wafers 71, are detachably held and supported by the wafer boat 3 in this embodiment. That is, the group of wafers 10 is held and supported such that it is inserted between above and below bare wafers 72. Unlike a case using the quartz wafers 71, the bare wafers 72 are removed from the wafer boat 3 during the cleaning treatment.

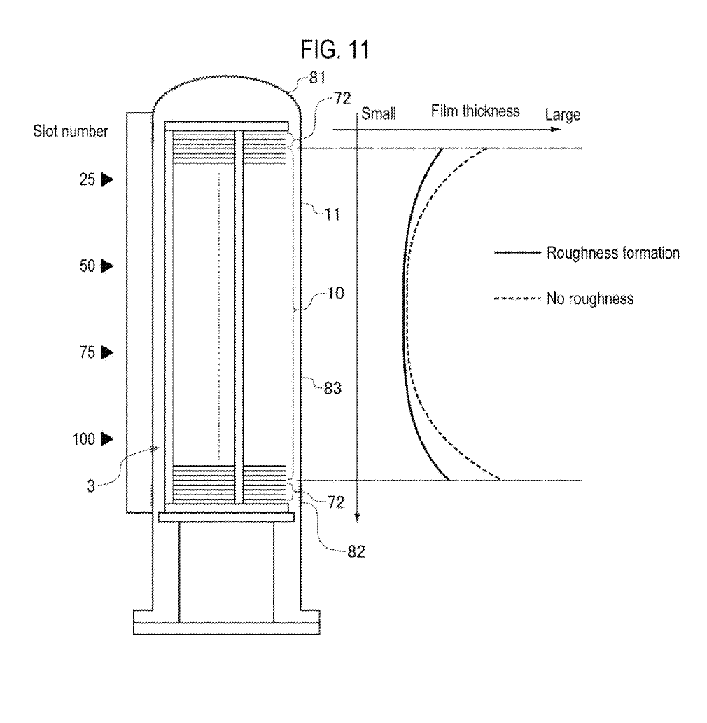

Similarly to FIG. 7, FIG. 11 shows the distribution of film thickness among the wafers 10 in the respective slots. In FIG. 11, a curve indicated by a dotted-line shows the distribution of film thickness among the wafers 10 when the film forming treatment is performed without forming the roughness to the reaction tube 11. In FIG. 11, a curve indicated by a solid-line shows the distribution of film thickness among the wafers 10 when the film forming treatment is performed by forming the roughness in the upper region 81 and lower region 82 as described above. As illustrated in the graph, by forming the roughness in the reaction tube 11, a gas is prevented from being excessively supplied to the wafers 10, which are disposed at the upper and lower sections of the wafer boat 3, in the group of wafers 10 held and supported by the wafer boat 3, thereby improving uniformity of the film thicknesses among the wafers 10, as in the first embodiment.

A region formed with the roughness above the group of wafers 10 in the reaction tube 11 may be either of the ceiling surface and the side circumferential surface. For a region below the group of wafers 10 in the reaction tube 11, the roughness formation is not limited to forming the roughness in the side circumferential surface but the roughness may be made in a surface of the bottom plate of the reaction tube 11, i.e., a surface of the lid 25.

### Third Embodiment

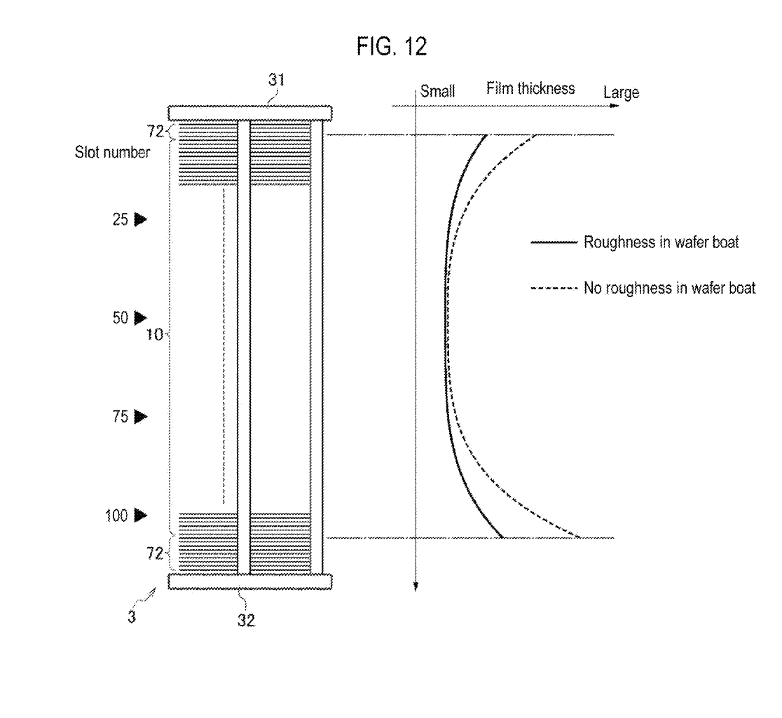

In the third embodiment, a vertical heat treatment apparatus 1 similar to that of the first embodiment is used, but the roughness described in the second embodiment is not formed, for example, in the inner surface of the reaction tube 11. Instead, the surface of each of the ceiling plate 31 and the bottom plate 32 of the wafer boat 3 is roughened as in the upper and lower regions 81 and 82 of the reaction tube 11 described in the second embodiment, so that the surface area S per unit region for each of the ceiling and bottom plates 31 and 32 divided by the surface area S0 per unit region of the wafer 10, i.e., S/S0 is set to be 0.06 or more. FIG. 12 shows a wafer boat 3 in which the roughness is formed as described above. For example, in the same manner as the second embodiment, a film forming treatment is performed with the wafers 10 and the bare wafers 72 mounted in the wafer boat 3. During the film forming treatment, the ceiling plate 31 and the bottom plate 32 perform the same function as the quartz wafers 71 described in the first embodiment and the upper and lower regions 81 and 82 of the reaction tube 11 described in the second embodiment, thereby adjusting the distribution of film thickness among the wafers 10.

To explain the surface area S per unit region of the ceiling plate 31 of the wafer boat 3 in detail, it is assumed that the ceiling plate 31 has no convex and concave portions and is cut to obtain a segment having an area A equal to that of a region surrounded by the contour of the wafer 10. If the surface area of a surface of the cut segment facing the treatment space in the reaction tube 11 is B, S is B/A. Since both a top side and a bottom side of the ceiling plate 31 face the treatment space, the surface area B is the sum of surface areas of the top and bottom sides. The surface area S per unit region of the bottom plate 32 of the wafer boat 3 is calculated in the same manner. The bottom side of the bottom plate 32 is covered by a stage 39 (see FIG. 1) for supporting the wafer boat 3 and does not face the treatment space. Thus, the surface area B becomes the surface area of the top side.

The graph of FIG. 12 shows a relationship between film thicknesses and slots of the wafers 10, as in the graphs of the other figures. A curve indicated by a dotted-line shows the distribution of film thickness among the wafers 10 when the film forming treatment is performed without forming the roughness in the ceiling plate 31 and the bottom plate 32. A curve indicated by a solid-line shows the distribution of film thickness among the wafers 10 when the film forming treatment is performed in the wafer boat 3 formed with the roughness.

### Fourth Embodiment

In the fourth embodiment, the same vertical heat treatment apparatus 1 as that of the first embodiment is used, and the wafer boat 3 is configured in the same manner as the first embodiment. In the fourth embodiment, wafers 10 and bare wafers 76 are held and supported in the wafer boat 3. The bare wafer 76 is configured to have the same shape as the bare wafer 72 but is made of quartz, instead of Si. When the surface area S per unit region of the bare wafer 76 is obtained in the same manner as the first embodiment, the relationship S/S0 with the surface area S0 per unit region of the wafer 10 is set to be less than 1.0.

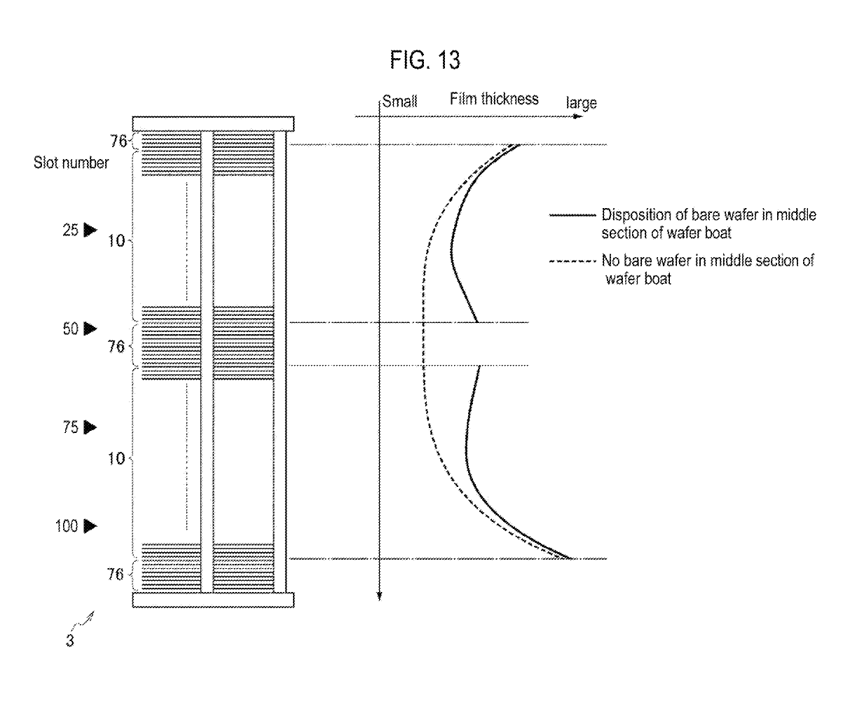

As shown in FIG. 13, slots in which the wafers 10 and 76 are mounted are different from those of the second and third embodiments. The bare wafers 76 are mounted in a plurality of slots at an upper section of the wafer boat 3 and in a plurality of slots at a lower section thereof as in the second and third embodiments. In addition, the bare wafers 76 are mounted in slots of which numbers are consecutive in the middle section of the wafer boat 3. In the example of FIG. 13, the bare wafers 76 are consecutively mounted in slots around Slot Nos. 50 to 60. The wafers 10 are disposed in slots in which the bare wafers 76 are not disposed.

Also in the fourth embodiment, the filming forming treatment and the cleaning treatment are performed in the same manner as the other embodiments. Since a plurality of bare wafers 76 are mounted in the middle section of the wafer boat 3, the consumption amount of the gas is reduced in the vicinity of the middle section during the film forming treatment. Therefore, the supply amount of a gas is increasing for the wafers 10 mounted in slots close to the slots with the bare wafers 76 mounted.

In FIG. 13, a curve indicated by a dotted-line shows the distribution of film thickness among the wafers 10 when the film forming treatment is performed with the bare wafers 76 mounted only at the upper and lower sections of the wafer boat 3. A curve indicated by a solid-line shows the distribution of film thickness among the wafers 10 when the film forming treatment is performed with the bare wafers 76 disposed also in the middle section of the wafer boat 3 as described above. As shown in the respective graphs, when the bare wafers 76 are disposed in the middle section, the consumption amount of a gas in the middle section is suppressed as described above. Hence, from the upper and lower sections of the wafer boat 3 toward the middle section, the film thickness decreases once and then increases. By means of such distribution of film thickness, a variation in film thickness is suppressed as compared with the case without the bare wafers 76 disposed in the middle section.

Since bare wafers 76 are made of quartz as described above, they are loaded into the reaction tube 11 and cleaned along with the wafer boat 3 during the cleaning treatment, as in the first embodiment. In the same manner as the quartz wafers 71 of the first embodiment, the bare wafers 76 may be fixed or detachably attached to the wafer boat 3. Although the plurality of bare wafers 76, which are plate-shaped members between the target substrates, are mounted in the middle section of the wafer boat 3 in order to sufficiently improve the supply distribution of a gas, only one bare wafer 76 may be mounted.

The fourth embodiment may be combined with the other embodiments. Specifically, the bare wafers 76 are used as the wafers mounted respectively in the plurality of slots at the upper and lower sections of the wafer boat 3 in FIG. 13. However, when combined with the first embodiment, the film forming treatment is performed with, for example, the quartz wafers 71 mounted, instead of the bare wafers 76. Moreover, the film forming treatment may be performed while the wafer boat 3 mounted with the respective wafers 10 and 76 as shown in FIG. 13 is loaded into the reaction tube 11 with a roughened inner surface as described in the second embodiment. Further, the film forming treatment may be performed while the respective wafers 10 and 76 are mounted as shown in FIG. 13 in the wafer boat 3 with the ceiling plate 31 and bottom plate 32 roughened as described in the third embodiment. That is, the film forming treatment may be performed in a state that one bare wafer 76 or a plurality of bare wafers 76 are disposed between the wafers 10 as described above and members made of quartz and having relatively large surface areas are disposed above and below the wafers 10 in order to adjust a gas distribution.

Although the vertical heat treatment apparatus 1 is configured to perform ALD, the present disclosure may be applied to a batch type treatment apparatus for forming a film by supplying a gas. Thus, the present disclosure may be applied to a vertical heat treatment apparatus for performing CVD. Further, the respective embodiments described above may be implemented in combination with one another. For example, in the first embodiment, the film forming treatment may be performed using the reaction tube 11 formed with the roughness as described in the second embodiment. For applying the fourth embodiment to the first to third embodiments, bare wafers 76 may be disposed between one group of wafers 10 and another group of wafers 10. Further, in the second and third embodiments, the film forming treatment may be performed by mounting the bare wafers 76 instead of the bare wafers 72.

Meanwhile, it may be considered that the wafers 10 are subjected to different treatments for every lot and they are mounted in the wafer boat 3 in a state that line width of patterns or thickness of a film formed with convex and concave portions are different. That is, it may be considered that wafers 10 for every lot transported to the vertical heat treatment apparatus 1 have different surface areas. In this case, for example, plural kinds of quartz wafers 71 in the first embodiment, which are detachably attached to the wafer boat 3 and have different surface areas, are prepared. Among the plural kinds of quartz wafers 71, quartz wafers 71 to be mounted in the wafer boat 3 may be selected according to the lot of wafers 10 on which the film forming treatment is performed in the vertical heat treatment apparatus 1. Accordingly, the amount of a gas supplied to the wafers 10 at the upper and lower sections of the wafer boat 3 can be controlled for every lot of wafers 10, thereby further improving uniformity of film thicknesses of the wafers 10 among respective slots.

### Fifth Embodiment

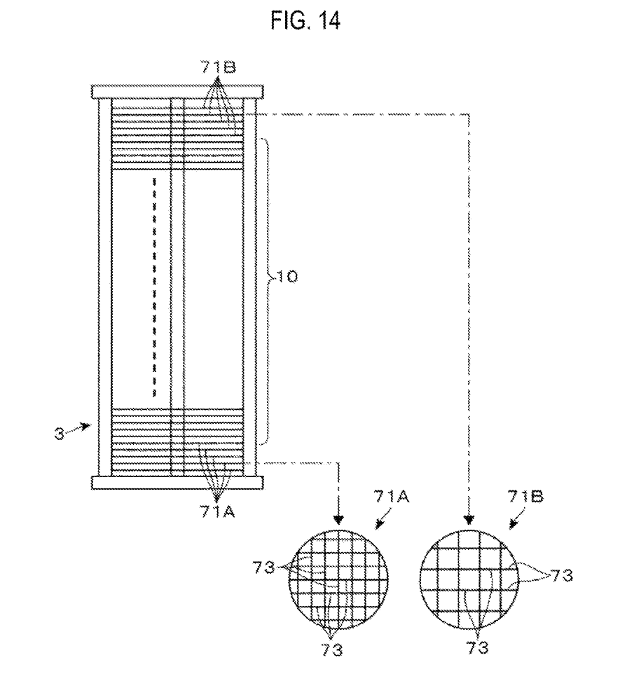

The fifth embodiment will be described with a focus on differences from the first embodiment with reference to FIG. 14 that shows an arrangement of the wafers in the wafer boat 3. In the same manner as in the first embodiment, the fifth embodiment is configured such that quartz wafers 71 are disposed in a plurality of slots at an upper section and a plurality of slots at a lower section among the slots of the wafer boat 3, and a film forming treatment is performed with the wafers 10 disposed in slots where quartz wafers 71 are not disposed. In the fifth embodiment, however, quartz wafers 71A having a first surface area and quartz wafers 71B having a second surface area different from the first surface area are used as the quartz wafers 71. For example, the quartz wafers 71A and 71B are configured to be detachably attached to the wafer boat 3. Similarly to the quartz wafer 71 in the first embodiment, if a surface area per unit region of the quartz wafer 71 is S and a surface area per unit region of the wafer 10 is S0, each of the quartz wafers 71A and 71B is configured such that S/S0 is set to be 0.06 or more.

At the end of each arrow of FIG. 14, a schematic plan view of each of the quartz wafers 71A and 71B is illustrated. For example, the quartz wafers 71A and 71B have the same contour as each other when seen from the top. In other words, the quartz wafers 71A and 71B have the same area and have the same thickness as each other when seen from the top. In FIG. 14, the reference numeral 73 designates grooves formed on the surfaces of the quartz wafers 71A and 71B. As the number of grooves 73 formed in the quartz wafer 71A is larger than that of grooves 73 formed in the quartz wafer 71B, a surface area of the quartz wafer 71A is greater than that of the quartz wafer 71B. In this example, if surface areas of the quartz wafers 71A and 71B are compared with a surface area of a bare wafer 72 having the same size as the quartz wafers 71A and 71B, the surface area of the quartz wafer 71A is 30 times greater than that of the bare wafer 72 and the surface area of the quartz wafer 71B is 10 times greater than that of the bare wafer 72.

FIG. 14 shows a state where the quartz wafers 71A are disposed in a plurality of slots at the lower section and the quartz wafers 71B are disposed in a plurality of slots at the upper section. With this arrangement, uniformity of film thickness distribution among the wafers 10 can be improved as compared with a case where the quartz wafers 71A are disposed in a plurality of slots at the upper and lower sections, as will be described later in relation to an Evaluation Test. If the film forming treatment is performed while the quartz wafers 71A are disposed also in slots where the quartz wafers 71B are disposed in the fifth embodiment, a large amount of processing gas (film forming gas) is consumed in the quartz wafers 71A. Accordingly, the processing gas hardly spreads out to a central portion in a height direction of the wafer boat 3 which is relatively largely spaced apart from the quartz wafers 71A, and thus reduction in film thicknesses of wafers 10 occurs at the central portion in the height direction, as will be descried later in relation to an Evaluation Test. In the fifth embodiment, an amount of processing gas supplied to each of the wafers 10 is finely and closely controlled by using the quartz wafers 71A and 71B together, thereby preventing a supply amount of processing gas to the central portion in the height direction of the wafer boat 3, which is spaced apart relatively far from one of the respective quartz wafers 71A and 71B, from being significantly reduced. Accordingly, uniformity of film thicknesses among the wafers 10 is improved.

In the example shown in FIG. 14, the quartz wafers 71A having a relatively large surface area are disposed in the lower section of the wafer boat 3 and the quartz wafers 71B having a relatively small surface area are disposed in the upper section of the wafer boat 3. As shown in FIG. 1, the exhaust port 67 is open below the reaction tube 11 into which the wafer boat 3 is carried. More specifically, the exhaust port 67 is open, for example, below the wafer boat 3. Therefore, concentration of a film forming gas easily becomes higher in the lower section of the wafer boat 3 than in the upper section of the wafer boat 3. For this reason, the quartz wafers 71 having a relatively large surface area are disposed in the lower section of the wafer boat 3, thereby adsorbing a larger amount of film forming gas in the lower section of the wafer boat 3 in comparison with in the upper section of the wafer boat 3. By adsorbing a larger amount of film forming gas in the lower section of the wafer boat 3 according to the above-described manner, it is possible to further increase the uniformity of film thicknesses among the wafers W. Alternatively, it may be configured that the quartz wafers 71A are disposed in the lower section of the wafer boat 3 and the quartz wafers 71B are disposed in the upper section of the wafer boat 3. Such arrangement of the quartz wafers 71A and 71B is effective when the exhaust port 67 is open in an upper portion of the reaction tube 11, more specifically, when the exhaust port 67 is open, for example, above the wafer boat 3.

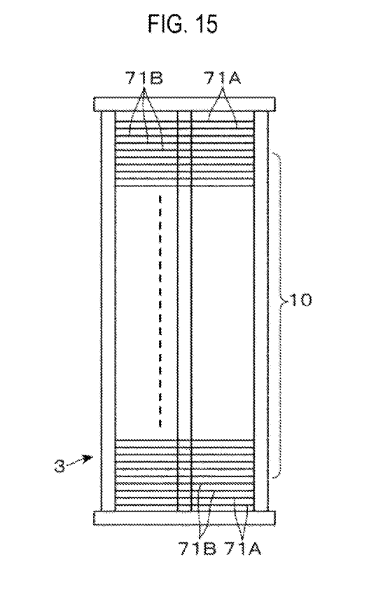

In addition, as shown in FIG. 15, the film forming treatment may be performed with both of the quartz wafers 71A and 71B disposed below and above a region in the wafer boat 3 where the wafers 10 are disposed. In the example shown in FIG. 15, in a plurality of slots at the upper section of the wafer boat 3, the quartz wafers 71A are disposed in the upper side and the quartz wafers 71B are disposed in the lower side. In addition, in a plurality of slots at the lower section of the wafer boat 3, the quartz wafers 71A are disposed in the lower side and the quartz wafers 71B are disposed in the upper side. If the quartz wafers 71A having a large surface area are disposed close to the wafers 10, an excessively small amount of processing gas is supplied to the wafers 10 because a large amount of processing gas is adsorbed onto the quartz wafers 71A, which may result in a reduction in film thickness of the wafers 10. For this reason, the quartz wafers 71A and 71B are arranged in the above-described manner.

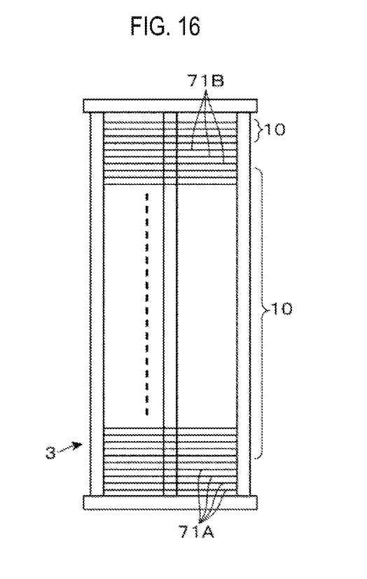

In the example arrangement shown in FIG. 14, the quartz wafers 71B are disposed in slots at the upper section. However, as shown in FIG. 16, the quartz wafers 71B may be disposed in slots lower than the slots at the upper section such that the wafers 10 are disposed in slots above and below the slots in which the quartz wafers 71B are disposed. Also, the quartz wafers 71A are not limited to be disposed in slots at the lower section, but the quartz wafers 71A may be disposed in slots above the slots at the lower section such that the wafers 10 are disposed in slots above and below the slots in which the quartz wafers 71A are disposed. In this case, for the same reason as discussed above, there is a concern that a reduction in film thickness of the wafers 10 disposed in the slots close to the quartz wafers 71A occurs. Accordingly, from the viewpoint of reducing the number of wafers 10 disposed close to the quartz wafers 71A, the quartz wafers 71A may be preferably disposed in the slots at the lower section. In addition, while a plurality of quartz wafers 71A and a plurality of quartz wafers 71B are disposed in the example arrangements as described above, only one quartz wafer 71A and/or only one quartz wafer 71B may be disposed in the wafer boat 3.

The surface areas of the quartz wafers 71A and 71B are not limited to the configuration described above. If the quartz wafers 71A and 71B have relatively large surface areas and a difference between the surface areas of the quartz wafers 71A and 71B is small, film thicknesses of wafers 10 decrease at the central portion in the height direction of the wafer boat 3 as in the case of disposing the quartz wafers 71A only in the wafer boat 3 as described above. If the quartz wafers 71A and 71B have relatively small surface areas and a difference between the surface areas of the quartz wafers 71A and 71B is small, there is a concern that the processing gas supplied to the upper and lower sections of the wafer boat 3 is not sufficiently adsorbed onto the quartz wafers 71A and 71B. Thus, each of the quartz wafers 71A and 71B is configured such that the surface area of the quartz wafer 71A divided by the surface area of the quartz wafer 71B is set to be 0.01 or more and 0.9 or less.

The quartz wafers 71A and 71B have different surface areas as described above. Herein, the different surface areas mean that the quartz wafers 71A and 71B are designed and manufactured to have different surface areas rather than that they have different surface areas due to an error in a manufacturing process. In the example as described above, the surface areas of the quartz wafers 71A and 71B are made different according to the number of grooves 73. However, besides the number of grooves 73, the surface areas of the quartz wafers 71A and 71B may be made different by setting widths, depths or lengths of the grooves 73 differently. In addition, the film forming treatment may be performed with three or more kinds of quartz wafers 71 having different surface areas disposed in the wafer boat 3.

In a case where some amount of processing gas is adsorbed onto the quartz wafers 71 at the upper and lower sections of the wafer boat 3, whether an appropriate film thickness distribution among the wafers 10 mounted in the wafer boat 3 is obtained or not is determined based on the surface area of the wafers 10. Thus, for example, the quartz wafers 71B having relatively small surface areas are prepared such that they have several different surface areas. Then, film forming treatments may be performed using the quartz wafers 71A having relatively large surface areas throughout the film forming treatments, while the quartz wafers 71B having appropriate surface areas are selected based on the surface area of wafers 10 to be processed and the selected quartz wafers 71B are mounted in the wafer boat 3 for each of the film forming treatments. By reusing the quartz wafers 71A as described above, it is possible to suppress the number of quartz wafers 71A to be manufactured. In addition, by replacing the quartz wafers 71B as described above, a supply amount of the processing gas to each of the wafers 10 can be appropriately controlled. The above-described method is effective because patterns of the wafers 10 are being miniaturized and the wafers 10 subjected to a film forming treatment are not limited to have a uniform surface area.

The fifth embodiment may be also combined with the other embodiments described above. For example, the quartz wafers 71A and 71B may be transferred by the transferring/mounting mechanism (transfer mechanism) for transferring and mounting the wafers 10 with respect to the wafer boat 3. In addition to dispose the quartz wafers 71A and 71B in the wafer boat 3, convex and concave portions may be formed in the reaction tube 11 as described in the second embodiment, the ceiling plate 31 and/or the bottom plate 32 of the wafer boat 3 may be roughened as described in the third embodiment, or the bare wafers 76 may be disposed in the wafer boat 3 as described in the fourth embodiment.

If a film forming treatment is performed using the quartz wafers 71 having the same surface area only under a condition that the quartz wafers 71 and the bare wafers 72 are configured to have the same contour and the surface area of the quartz wafers 71 is greater than the surface area of the bare wafers 72 by three times or more, it is thought that a reduction in film thickness of the wafers 10 will occur at the central portion in the height direction of the wafer boat 3, as will be described later in Evaluation Test. The fifth embodiment is effective, in particular, for improving the film thickness of the wafers 10 at the central portion in the height direction of the wafer boat 3, for example, when the surface area of the quartz wafers 71A is greater than the surface area of the bare wafers 72 by three times or more. The quartz wafers 71B are configured to have a surface area smaller than that of the quartz wafers 71A.

In the fifth embodiment, the quartz wafers 71A and 71B are disposed to adjust distribution of a gas supplied to each wafer 10. However, instead of the quartz wafers 71A and 71B, wafers made of a material other than quartz may be disposed in order to adjust distribution of a gas supplied to the wafers 10. Such wafers may have the same configuration as the quartz wafers 71A and 71B except for the material. For example, alumina (aluminum oxide), SiC (silicon carbide) or glassy carbon may be used as the material other than quartz. Also, a film forming treatment may be performed in a state that the bare wafers 76 and/or patterned wafers other than the wafers 10 are mounted between the quartz wafers 71A and the wafers 10 and between the quartz wafers 71B and the wafers 10. Also, the bare wafers 76 and the patterned wafers are not limited to those made of quartz.

The quartz wafers 71A and 71B may have patterns (roughness), i.e., the grooves 73, for increasing the surface areas thereof on both main surfaces (the top side and the bottom side) as shown in FIG. 1 or on only one of the two main surfaces. Hereinafter, a main surface on which patterns are formed will be referred to as a roughened surface, and another main surface on which patterns are not formed will be referred to as a non-roughened surface. For example, when each of the quartz wafers 71A and 71B is configured to have a roughened surface and a non-roughened surface, each of the quartz wafers 71A and 71B is supported and transported in a state where the roughened surface thereof is supported by the transferring/mounting mechanism and the non-roughened surface thereof is facing upward. By transporting the quartz wafers 71A and 71B in this manner, the quartz wafers 71A and 71B are delivered between the wafer boat 3 and, for example, a carrier which accommodates the quartz wafers 71A and 71B and transfers them to the vertical heat treatment apparatus 1. Thus, the quartz wafers 71A and 71B are mounted in the wafer boat 3 with the roughened surfaces of the quartz wafers 71A and 71B facing upward.

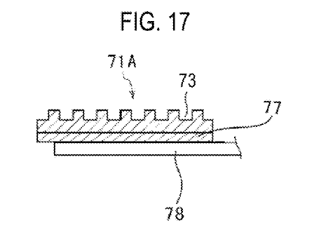

If the quartz wafers 71A and 71B that include the roughened surfaces and the non-roughened surfaces are repeatedly used to laminate SiN films, different amounts of a film forming gas are adsorbed onto the roughened surfaces and the non-roughened surfaces. As a result, stresses applied to the non-roughened surfaces (bottom sides) gradually increase, and thus the quartz wafers 71A and 71B are likely to be bent so that central portions of the roughened surfaces as top sides become higher than peripheral portions thereof. In addition, it is thought that, as the quartz wafers 71A and 71B are bent gradually, it becomes difficult to transport the quartz wafers 71A and 71B in a state where the bottom sides of the quartz wafers 71A and 71B are supported by the transferring/mounting mechanism. In order to prevent this problem, in some embodiments, stress relaxation films 77, which suppress stresses applied to the non-roughened surfaces and prevent the quartz wafers 71A and 71B from being bent, may be formed on the non-roughened surfaces of the quartz wafers 71A and 71B as shown in the schematic view of FIG. 17, by, for example, a vapor deposition method.

The stress relaxation films 77 are composed of silicon oxide (SiO₂) or amorphous silicon (α-Si). The reason for suppressing the stresses and preventing the quartz wafers 71A and 71B from being bent by forming the stress relaxation films 77 made of materials described above is that compressive stresses possessed by the SiN films can be canceled by tensile stresses possessed by the stress relaxation films 77. As long as a film has such an effect, the film can be used as the stress relaxation film 77 even though the film is made of a material other than materials described above. In FIG. 17, the reference numeral 78 is a support portion of the transferring/mounting mechanism that supports the non-roughened surfaces of the quartz wafers 71A and 71B.

By performing the film forming treatment repeatedly, a film thickness of SiN films formed on the surfaces of the quartz wafers 71A and 71B increases gradually. However, it is thought that, for example, in a case of using a stress relaxation film 77 composed of α-Si, an occurrence of bending of the quartz wafers 71A and 71B is suppressed if a film thickness of the SiN film divided by a film thickness of the α-Si film is 0.43 or less. If the film thickness of the SiN film divided by the film thickness of the α-Si film is greater than 0.43, it is thought that bending occurs in the quartz wafers 71A and 71B. Thus, it is necessary to clean the quartz wafers 71A and 71B. For example, when the stress relaxation film 77 is composed of SiO₂, it is thought that an occurrence of bending of the quartz wafers 71A and 71B is suppressed if a film thickness of the SiN film divided by a film thickness of the SiO₂ film is 1.0 or less. If the film thickness of the SiN film divided by the film thickness of the SiO₂ film is greater than 1.0, it is thought that bending occurs in the quartz wafers 71A and 71B. Thus, it is necessary to perform cleaning of the quartz wafers 71A and 71B. Accordingly, the film thickness of the stress relaxation film 77 is set by considering, for example, the number of times for repeatedly using the quartz wafer 71A and 71B or the film thickness of the SiN film formed by performing the film forming treatment once. The stress relaxation film 77 is formed in the quartz wafers 71A and 71B prior to using the quartz wafers 71A and 71B in the film forming treatment.

### (Evaluation Test)

Evaluation tests performed according to the present disclosure will be described. In Evaluation Test 1, as described in the BACKGROUND, bare wafers 72 were mounted in a plurality of slots at an upper section of the wafer boat 3 and a plurality of slots at a lower section of the wafer boat 3, wafers 10 were mounted in other slots, and a film forming treatment was performed in the vertical heat treatment apparatus. After the film forming treatment, the film thickness of the wafer 10 in each slot was measured. Further, in Evaluation Test 2, test wafers were mounted instead of the bare wafers 72 and a film forming treatment was performed. The test wafer has the same surface area as the wafer 10 and is made of the same material as the wafer 10. The surface area of both the wafer 10 and the test wafer is three times greater than that of the bare wafer 72.

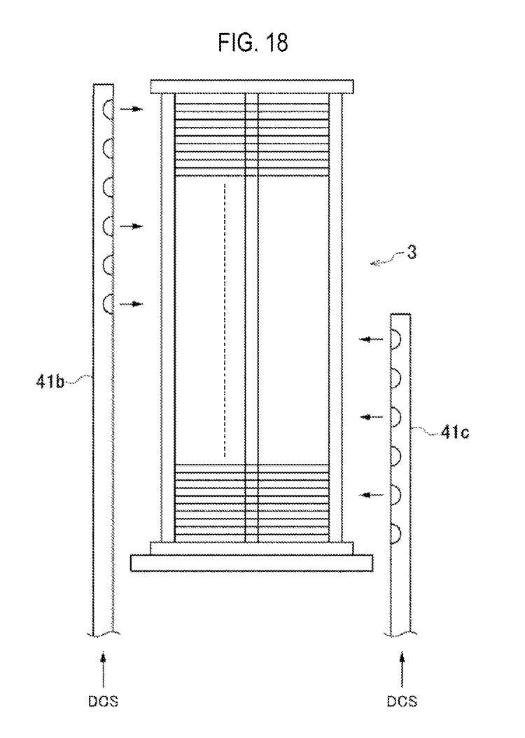

Although an apparatus configured to be approximately similar to the apparatus of the aforementioned embodiments was used as the vertical heat treatment apparatus used in this evaluation test, an injector for supplying DCS gas is configured as shown in FIG. 18. That is, the injector was configured such that a raw material gas supply nozzle 41b for supplying a gas to the upper section of the wafer boat 3 and a first raw material gas supply nozzle 41c for supplying a gas to the lower section of the wafer boat 3 were installed and DCS gas was supplied from each of the nozzles 41b and 41c.

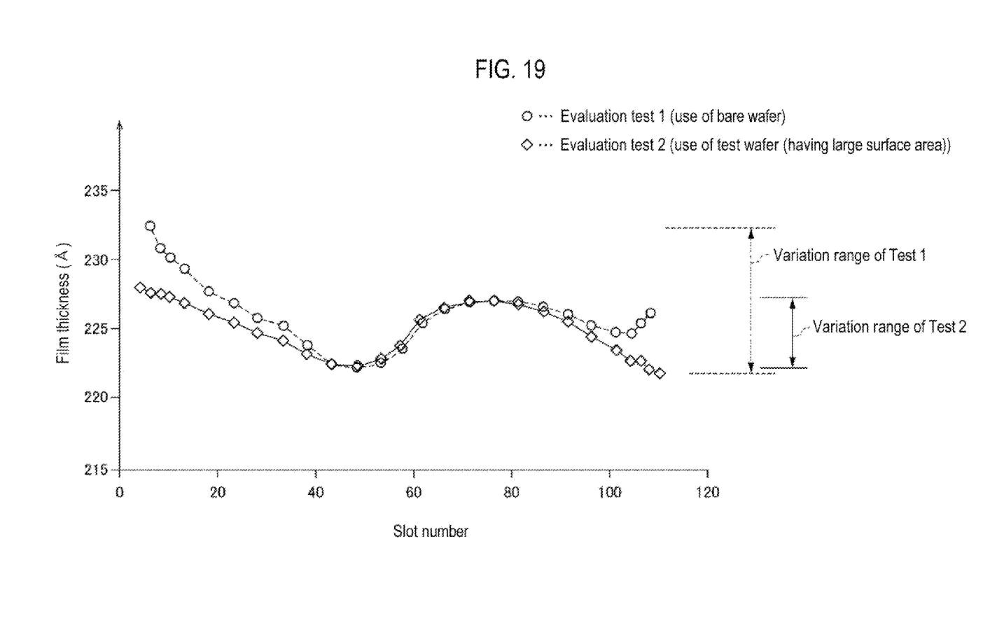

FIG. 19 is a graph showing results of Evaluation Tests 1 and 2. The slot numbers are represented on the abscissa axis, and the measured film thicknesses (unit: Å) of the wafers 10 are represented on the ordinate axis. Further, in each of the evaluation tests, a variation range of film thicknesses among the slots mounted with the wafers 10 is indicated by an arrow. As clearly seen from FIG. 19, in Evaluation Test 1, the film thicknesses of the wafers 10 in the slots close to slots at the upper and lower sections, i.e., in the slots close to slots mounted with the bare wafers 72, are larger than those in Evaluation Test 2. For this reason, in Evaluation Test 1, a variation in film thickness of the wafers 10 among the slots is larger than that in Evaluation Test 2. On the contrary, in Evaluation Test 2, film thicknesses of the wafers 10 in the slots at the upper and lower sections are prevented from increasing, thereby suppressing the variation in film thickness among the slots. From the results of these tests, as described in each of the embodiments, it can be found that it is effective to install members having large surface areas above and below a region in which a group of wafers 10 is disposed.

Next, Evaluation Test 3-1 and Evaluation Test 3-2 will be explained. In Evaluation Test 3-1, a number of wafers 10 were disposed in the slots of the wafer boat 3 as shown in FIG. 1. In addition, quartz wafers 71 were disposed in a plurality of slots below the slots in which the wafers 10 were disposed. In this evaluation test, the surface area S per unit region of the quartz wafer 71 divided by the surface area S0 per unit region of the wafer 10, i.e., S/S0 is set to 3/5=0.6). Each of the wafers 10 and the quartz wafers 71 was disposed in the wafer boat 3 in the above-described manner and a film forming treatment as described in the embodiments of the present disclosure was performed. After the film forming treatment, film thicknesses of 20 sheets of wafers 10 disposed in slots above the slots in which quartz wafers 71 were disposed were measured. The wafers 10 used in this film thickness measurement were disposed in the wafer boat 3 adjacent to each other during the film forming treatment, and among them, the wafer 10 disposed on the lowest side of the wafer boat 3 has been disposed adjacent to the quartz wafers 71.

In Evaluation Test 3-2, except for disposing bare wafers 72, instead of the quartz wafers 71, into the slots in which the quartz wafers 71 were disposed in Evaluation Test 3-1, the film forming treatment was performed in the same manner as in Evaluation Test 3-1. In addition, film thicknesses of 20 sheets of the wafers 10 disposed above the bare wafers 72 were measured in the same manner as in Evaluation Test 3-1.

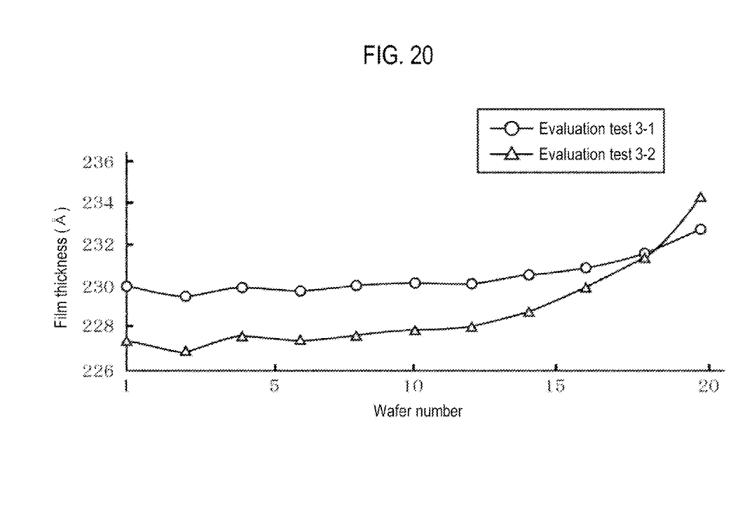

FIG. 20 is a graph showing results of Evaluation Tests 3-1 and 3-2. The ordinate axis of the graph corresponds to the measured film thicknesses (unit: A). Wafer numbers assigned to the wafers 10 used in the measurement are represented on the abscissa axis of the graph. Among the wafers 10 used in the measurement, the wafer 10 disposed uppermost in the wafer boat 3 is designated by the wafer number 1, and the wafer number increases as the wafer 10 disposed closer to a lower end of the wafer boat 3. As shown in the graph, in Evaluation Test 3-1 as compared with Evaluation Test 3-2, an increase in film thickness of the wafers 10 designated by relatively large wafer numbers is suppressed with respect to that of the wafers 10 designated by relatively small wafer numbers. A difference between the maximum and minimum values of film thickness was calculated. The difference was 3.40 Å in Evaluation Test 3-1 and 7.41 Å in Evaluation Test 3-2. The difference in Evaluation test 3-1 is smaller than that in Evaluation Test 3-2.

As described above, a variation in film thickness among wafers 10 is suppressed in Evaluation Test 3-1 as compared with Evaluation Test 3-2. From the results of Evaluation Tests 3-1 and 3-2, it is thought that, if quartz wafers 71 are disposed in slots above the slots in which the wafers 10 are disposed, the film thicknesses of the wafers 10 disposed in the vicinity of the quartz wafers 71 are also suppressed from being excessively large. Accordingly, from Evaluation Tests 3-1 and 3-2, it was confirmed that distribution of film thickness of the wafers 10 could be changed by using the quartz wafers 71. It is thought that, by disposing the quartz wafers 71 having different surface areas as described in the fifth embodiment, the film forming gas supplied to wafers 10 can be more accurately adjusted and distribution of film thickness among the wafers 10 can be made more uniform.

### (Evaluation Test 4)

In Evaluation Test 4, as described in the first embodiment, a film forming treatment was performed by disposing silicon wafers having a surface on which patterns are formed in a plurality of slots at the upper section of the wafer boat 3 and in a plurality of slots at the lower section of the wafer boat 3 and by disposing the wafers 10 in slots in which the silicon wafers were not disposed. Then, film thicknesses formed in the wafer 10 of each slot were measured. The silicon wafers having surface areas larger than that of the bare wafer 72, which has the same contour as the silicon wafers, by 30 times, 10 times, 5 times and 3 times, respectively, were prepared. The silicon wafers having different surface areas were used for different film forming treatments, while the silicon wafers having the same surface area were disposed in each slot in order to perform one film forming treatment.

The film forming treatments were performed using silicon wafers having surface areas larger than that of the bare wafer 72 by 30 times (hereinafter, referred to as 30 times silicon wafers) in Evaluation Test 4-1, using silicon wafers having surface areas larger than that of the bare wafer 72 by 10 times (hereinafter, referred to as 10 times silicon wafers) in Evaluation Test 4-2, using silicon wafers having surface areas larger than that of the bare wafer 72 by 5 times (hereinafter, referred to as 5 times silicon wafers) in Evaluation Test 4-3, and using silicon wafers having surface areas larger than that of the bare wafer 72 by 3 times (hereinafter, referred to as 3 times silicon wafers) in Evaluation Test 4-4, respectively.

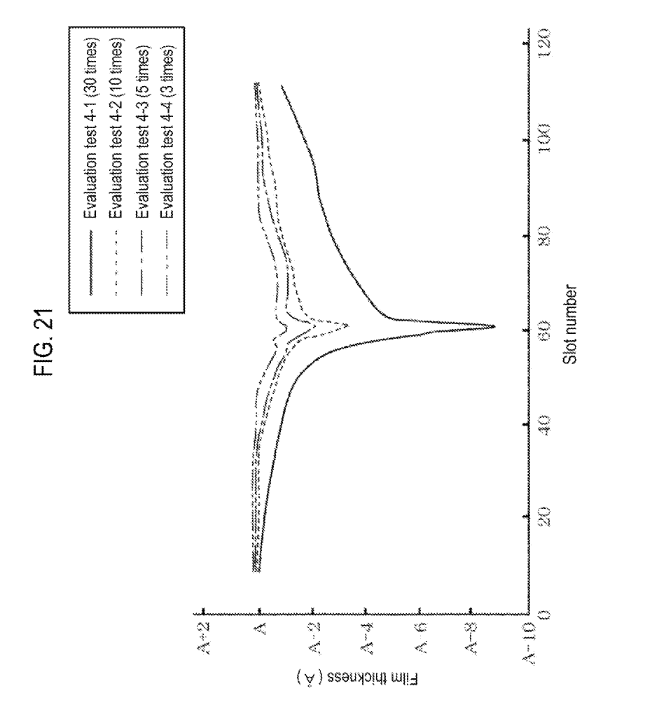

FIG. 21 is a graph showing the results of Evaluation Test 4. The slot numbers of the slots, in which wafers 10 were mounted, are represented on the abscissa axis of the graph and the measured film thicknesses are represented on the ordinate axis of the graph. In the graph of FIG. 21, a curve indicated by a solid-line, a curve indicated by a dotted-line, a curve indicated by a dashed-line, and a curve indicated by a two-dot chain line represent a distribution of film thickness (unit: A) of the wafers 10 measured in Evaluation Tests 4-1, 4-2, 4-3, and 4-4, respectively. From the graph of FIG. 21, in Evaluation Tests 4-1 to 4-4, it is confirmed that the film thicknesses of the wafers 10 mounted in the slot of No. 60, which is disposed at the central portion in the height direction of the wafer boat 3, and mounted in the slots in the vicinity of the slot of No. 60 were significantly reduced as compared with the film thicknesses of the wafers 10 mounted in the other slots. Particularly, in Evaluation Test 4-1 using 30 times silicon wafers, a large difference was observed between the film thickness of the wafer 10 mounted in the slot at the central portion of the wafer boat 3 and the film thicknesses of the wafers 10 mounted in the other slots. That is to say, it is confirmed that distribution of film thickness among the wafers 10 cannot be sufficiently improved by disposing the silicon wafers having the same surface area only. Also, it is thought that the same experimental results as in the case of disposing the silicon wafers will be obtained even if wafers made of other materials, e.g., the aforementioned quartz wafers 71, are disposed instead of the silicon wafers.

### (Evaluation Test 5)

In Evaluation Test 5-1, a film forming treatment was performed in the same manner as in Evaluation Test 4-1. However, in Evaluation Test 5-1, 30 times silicon wafers were disposed in two slots above a group of slots, in which the wafers 10 were disposed, and in seven slots below the group of slots. In Evaluation Test 5-2, a film forming treatment was performed in the same manner as in Evaluation Tests 5-1, except that 10 times silicon wafers were disposed in five slots above a group of slots in which the wafers 10 were disposed and 30 times quartz wafers 71 were disposed in seven slots below the group of slots in which the wafers 10 were disposed. In both of Evaluation Tests 5-1 and 5-2, film thicknesses of the wafers 10 were measured after the film forming treatment. Then, a difference between the maximum and minimum values in film thicknesses of the wafers 10 was calculated.

The difference was 6.99 Å and 5.67 Å in Evaluation Test 5-1 and Evaluation Test 5-2, respectively. That is to say, in Evaluation Test 5-2, a variation in film thickness among the wafers 10 is suppressed. Accordingly, the effect of the present disclosure is also confirmed from Evaluation Test 5. It is also thought that the same experimental results as in the case of disposing the silicon wafers will be obtained in Evaluation Test 5, even if wafers made of other materials, e.g., the aforementioned quartz wafers 71, are disposed instead of the silicon wafers.

According to some embodiments of the present disclosure, a first plate-shaped member and a second plate-shaped member as gas distribution adjusting members are arranged above and below a region in which the plurality of target substrates held and supported by a substrate holding and supporting part are disposed, and the first plate-shaped member and the second plate-shaped member have different surface areas from each other. Thus, supply amounts of gas to upper and lower sections of the substrate holding and supporting part can be finely and closely adjusted, thereby improving uniformity in film thickness among films formed on the substrates. In addition, a gas distribution adjusting member made of quartz is hardly etched by a cleaning gas supplied to a reaction tube, which is a fluorine-based gas containing fluorine or a fluorine compound, as compared with that made of silicon. Accordingly, it is possible to clean the gas distribution adjusting members as well as the interior of the reaction tube by the cleaning gas, thereby reducing the burden on operation of an apparatus.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures.

What is claimed is:

1. A vertical heat treatment apparatus for performing a film forming treatment on a plurality of target substrates by heating the target substrates with a heating part in a state that the target substrates are held and supported by a substrate holding and supporting part in a vertical reaction chamber, each of the target substrates having a surface with convex and concave portions, the apparatus comprising:
a gas supply part that supplies a film forming gas into the reaction chamber; and
gas distribution adjusting members arranged above and below a region in which the plurality of target substrates held and supported by the substrate holding and supporting part are disposed,
wherein the gas distribution adjusting members include a first plate-shaped member with convex and concave portions and a second plate-shaped member with convex and concave portions, the first plate-shaped member and the second plate-shaped member being arranged above and below each other, and the first plate-shaped member and the second plate-shaped member being arranged above a bottom plate of the substrate holding and supporting part and below a ceiling plate of the substrate holding and supporting part, and
wherein the first plate-shaped member has a first surface area and the second plate-shaped member has a second surface area different from the first surface area.

2. The apparatus of claim 1, wherein the gas distribution adjusting members are made of quartz.

3. The apparatus of claim 1, wherein the second surface area divided by the first surface area is 0.01 or more and 0.9 or less.

4. The apparatus of claim 1, wherein the first plate-shaped member is arranged in one of a level above and below the region in which the target substrates are disposed and the second plate-shaped member is arranged in the other level.

5. The apparatus of claim 1, wherein the first plate-shaped member and the second plate-shaped member are configured to be transferred by a transfer mechanism that transfers the target substrates.

6. The apparatus of claim 1, wherein in at least one of the first plate-shaped member and the second plate-shaped member, the convex and concave portions are formed in one of two main surfaces of the plate-shaped member and a film for preventing the plate-shaped member from being bent is formed in the other one of the two main surfaces.

7. The apparatus of claim 1, wherein the gas distribution adjusting members include the ceiling plate of the substrate holding and supporting part, the ceiling plate having convex and concave portions formed thereon.

8. The apparatus of claim 1, wherein the gas distribution adjusting members include a ceiling portion of the reaction chamber, the ceiling portion having convex and concave portions formed thereon.

9. The apparatus of claim 1, wherein the gas distribution adjusting members include the bottom plate of the substrate holding and supporting part, the bottom plate having convex and concave portions formed thereon.

10. The apparatus of claim 1, wherein the gas distribution adjusting members include an inner wall portion of the reaction chamber arranged below the region in which the plurality of target substrates are disposed.

11. A method of operating a vertical heat treatment apparatus for performing a film forming treatment on a plurality of target substrates by heating the target substrates with a heating part in a state that the target substrates are held and supported by a substrate holding and supporting part in a vertical reaction chamber, each of the target substrates having a surface with convex and concave portions, the method comprising:
supplying a film forming gas into the reaction chamber by a gas supply part in a state that gas distribution adjusting members are arranged above and below a region in which the plurality of target substrates held and supported by the substrate holding and supporting part are disposed,
wherein the gas distribution adjusting members include a first plate-shaped member with convex and concave portions and a second plate-shaped member with convex and concave portions, the first plate-shaped member and the second plate-shaped member being arranged above and below each other, and the first plate-shaped member and the second plate-shaped member being arranged above a bottom plate of the substrate holding and supporting part and below a ceiling plate of the substrate holding and supporting part, and
wherein the first plate-shaped member has a first surface area and the second plate-shaped member has a second surface area different from the first surface area.

12. The method of claim 11, wherein the gas distribution adjusting members are made of quartz.

13. The method of claim 11, wherein the second surface area divided by the first surface area is 0.01 or more and 0.9 or less.

14. The method of claim 11, wherein the first plate-shaped member is arranged in one of a level above and below the region in which the target substrates are disposed and the second plate-shaped member is arranged in the other level.

15. The method of claim 11, wherein in at least one of the first plate-shaped member and the second plate-shaped member, the convex and concave portions are formed in one of two main surfaces of the plate-shaped member and a film for preventing the plate-shaped member from being bent is formed in the other one of the two main surfaces.

16. The method of claim 11, wherein the gas distribution adjusting members include a ceiling portion of the reaction chamber, the ceiling portion having convex and concave portions formed thereon.

17. The method of claim 11, wherein the gas distribution adjusting members include an inner wall portion of the reaction chamber arranged below the region in which the plurality of target substrates are disposed.
